(19) United States
(12) Patent Application Publication
(10) Pub. No.: US 2025/0266399 A1
(43) Pub. Date: Aug. 21, 2025

(54) SEMICONDUCTOR PACKAGE

(71) Applicant: Samsung Electronics Co., Ltd., Suwon-si (KR)

(72) Inventors: Wongil HAN, Suwon-si (KR); Byongjoo KIM, Suwon-si (KR); Minwoo SONG, Suwon-si (KR); Jongho LEE, Suwon-si (KR); Hojae KIM, Suwon-si (KR)

(73) Assignee: Samsung Electronics Co., Ltd., Suwon-si (KR)

(21) Appl. No.: 18/989,146

(22) Filed: Dec. 20, 2024

(30) Foreign Application Priority Data
Feb. 20, 2024 (KR) 10-2024-0024021

(51) Int. Cl. H01L 25/065; H01L 23/00; H01L 23/31; H01L 23/498; H01L 25/00; H01L 25/16; H05K 1/11; H05K 1/18; H10B 80/00; H10D 80/30

(52) U.S. Cl. CPC H01L 25/0657; H01L 23/3128; H01L 23/3157; H01L 24/32; H01L 24/48; H01L 24/73; H01L 25/165; H01L 25/50; H01L 23/49838; H01L 24/83; H01L 2224/32145; H01L 2224/32225; H01L 2224/48108; H01L 2224/48147; H01L 2224/48229; H01L 2224/48453; H01L 2224/48464; H01L 2224/73215; H01L 2224/73265; H01L 2224/83191; H01L 2225/06506; H01L 2225/0651; H01L 2225/06524; H01L 2225/06562; H01L 2924/386; H05K 1/111; H05K 1/181; H05K 2201/10515; H05K 2201/10795; H10B 80/00; H10D 80/30

(57) ABSTRACT

A semiconductor package includes a package substrate having first and second substrate pads thereon, a first semiconductor chip on the package substrate and including a first chip pad, a second semiconductor chip on the first semiconductor chip and including a second chip pad on a lower surface of the second semiconductor chip, a first bonding wire contacting the first substrate pad and the first chip pad, and a second bonding wire contacting the second substrate pad and the second chip pad. An uppermost portion of the second bonding wire is lower than or coplanar with the lower surface of the second semiconductor chip.

### CROSS-REFERENCE TO RELATED APPLICATION

This application claims benefit of and priority under 35 U.S.C. § 119 to Korean Patent Application No. 10-2024-0024021, filed on Feb. 20, 2024 in the Korean Intellectual Property Office (KIPO), the contents of which are herein incorporated by reference in their entirety.

### BACKGROUND

Example embodiments relate to semiconductor packages. More particularly, example embodiments relate to semiconductor packages including a plurality of semiconductor chips stacked on a substrate.

In a multi-chip package including a plurality of semiconductor chips stacked on a package substrate, chip pads on each of the semiconductor chips and substrate pads on the package substrate may be electrically connected to each other by bonding wires. In order to protect the bonding wires, a molding member on the package substrate may be thick.

### SUMMARY

Example embodiments provide a semiconductor package having enhanced electrical characteristics.

According to some example embodiments, there is provided a semiconductor package. The semiconductor package may include a package substrate having first and second substrate pads, a first semiconductor chip on the package substrate and including a first chip pad thereon, a second semiconductor chip on the first semiconductor chip and including a second chip pad on a lower surface of the second semiconductor chip, a first bonding wire contacting the first substrate pad and the first chip pad, and a second bonding wire contacting the second substrate pad and the second chip pad. An uppermost portion of the second bonding wire may be lower than or coplanar with the lower surface of the second semiconductor chip.

According to some example embodiments, there is provided a semiconductor package. The semiconductor package may include a package substrate having first and second substrate pads thereon, a lower semiconductor chip stack structure including first semiconductor chips, each of which may include a first chip pad, stacked on the package substrate in a vertical direction perpendicular to an upper surface of the package substrate, a second semiconductor chip on the lower semiconductor chip stack structure and including a second chip pad on a bottom surface of the second semiconductor chip, a first bonding wire contacting the first chip pad of a lowermost one of the first semiconductor chips and the first substrate pad, and a second bonding wire contacting the second substrate pad and the second chip pad. An upper surface of each of the first and second substrate pads may be lower than an upper surface of the lowermost one of the first semiconductor chips.

According to some example embodiments, there is provided a semiconductor package. The semiconductor package may include a package substrate having first and second substrate pads, a lower semiconductor chip stack structure including first semiconductor chips, each of which may include a first chip pad, stacked on the package substrate in a vertical direction substantially perpendicular to an upper surface of the package substrate, a second semiconductor chip on the lower semiconductor chip stack structure and including a second chip pad on a lower surface of the second semiconductor chip, a first adhesion layer contacting a portion of an upper surface of an uppermost one of the first semiconductor chips included in the lower semiconductor chip stack structure and a portion of the lower surface of the second semiconductor chip, a first bonding wire contacting the first chip pad of a lowermost one of the first semiconductor chips and the first substrate pad, a second bonding wire contacting the first chip pads of neighboring ones of the first semiconductor chips in the vertical direction, a third bonding wire contacting the second substrate pad and the second chip pad, and a molding member on the package substrate, covering the lower semiconductor chip stack structure, the first adhesion layer and the first to third bonding wires, and surrounding a sidewall of the second semiconductor chip. An upper portion of the third bonding wire may be lower than, coplanar, or coplanar with the lower surface of the second semiconductor chip.

In the semiconductor package in accordance with some example embodiments, the active layer of the uppermost one of the semiconductor chips stacked on the package substrate may face downwardly, and the bonding wire may be disposed between and electrically connect the conductive pad in the active layer and the conductive pad on the package substrate, and thus no bonding wire may be formed on the upper surface of the uppermost one of the semiconductor chips. Accordingly, the molding member on the package substrate and covering the semiconductor chips may not cover the upper surface of the uppermost one of the semiconductor chips in order to cover the bonding wire on the upper surface of the uppermost one of the semiconductor chips, so as to have a reduced thickness in the vertical direction.

### BRIEF DESCRIPTION OF THE DRAWINGS

FIG. 1 is a cross-sectional view illustrating a semiconductor package in accordance with some example embodiments.

FIG. 2 is a cross-sectional view illustrating a semiconductor package in accordance with some example embodiments.

FIGS. 3 to 6 are cross-sectional views illustrating a method of manufacturing a semiconductor package in accordance with some example embodiments.

FIG. 7 is a cross-sectional view illustrating a semiconductor package in accordance with some example embodiments.

FIGS. 8 and 9 are cross-sectional views illustrating a method of manufacturing a semiconductor package in accordance with some example embodiments.

FIG. 10 is a cross-sectional view illustrating a semiconductor package in accordance with some example embodiments.

FIG. 11 is a cross-sectional view illustrating a method of manufacturing a semiconductor package in accordance with some example embodiments.

FIG. 12 is a cross-sectional view illustrating a semiconductor package in accordance with some example embodiments.

FIG. 13 is a cross-sectional view illustrating a semiconductor package in accordance with some example embodiments.

### DETAILED DESCRIPTION OF EXAMPLE EMBODIMENTS

Hereinafter, example embodiments will be explained in detail with reference to the accompanying drawings. It will be understood that, although the terms “first,” “second,” and/or “third” may be used herein to describe various materials, layers, regions, pads, electrodes, patterns, structure and/or processes, these various materials, layers, regions, pads, electrodes, patterns, structure and/or processes should not be limited by these terms. These terms are only used to distinguish one material, layer, region, pad, electrode, pattern, structure or process from another material, layer, region, pad, electrode, pattern, structure or process. Thus, “first”, “second” and/or “third” may be used selectively or interchangeably for each material, layer, region, electrode, pad, pattern, structure or process respectively.

Hereinafter, a direction substantially parallel to an upper surface of the substrate may be referred to as a horizontal direction, and a direction substantially perpendicular to the upper surface of the substrate may be referred to as a vertical direction.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

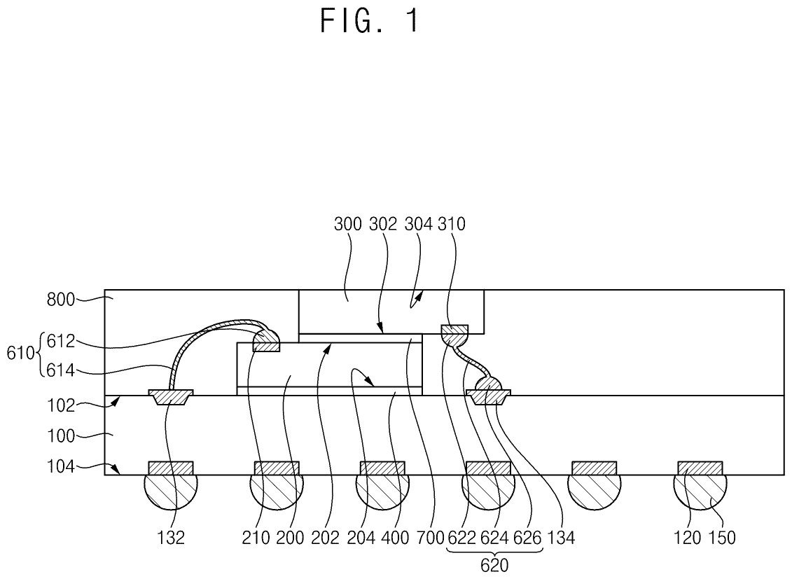

FIG. 1 is a cross-sectional view illustrating a semiconductor package in accordance with some example embodiments.

Referring to FIG. 1, the semiconductor package may include a package substrate 100, second and third conductive pads 132 and 134, a conductive connection member 150, first and second semiconductor chips 200 and 300, first and second bonding wires 610 and 620, first and second adhesion layers 400 and 700, and a molding member 800.

The package substrate 100 may include first and second surfaces 102 and 104 opposite to each other in the vertical direction, and may be a printed circuit board (PCB). The PCB may be a multi-layered circuit board including various circuit patterns, and FIG. 1 shows a first conductive pad 120 that is a part of the circuit patterns, and the second and third conductive pads 132 and 134 contacting the circuit patterns to be electrically connected thereto. In some example embodiments, a plurality of first conductive pads 120 may be spaced apart from each other in the horizontal direction, a plurality of second conductive pads 132 may be spaced apart from each other in the horizontal direction (e.g. a direction into the page as depicted in FIG. 1), and plurality of third conductive pads 134 may be spaced apart from each other in the horizontal direction (e.g. a direction into the page as depicted in FIG. 1). The first to third conductive pads 120, 132 and 134 may be disposed in the package substrate 100, and thus may also be referred to as first to third substrate pads 120, 132 and 134.

In some example embodiments, each of the second and third conductive pads 132 and 134 may include a lower portion in a groove on the first surface 102 of the package substrate 100, and an upper portion that is disposed on and contacts the lower portion and protrudes above the first surface 102 of the package substrate 100. A width of the upper portion of each of the second and third conductive pads 132 and 134 may be greater than a width of the lower portion thereof.

Each of the second and third conductive pads 132 and 134 may include a metal, e.g., nickel, copper, aluminum, gold, etc.

The conductive connection member 150 may be disposed beneath the second surface 104 of the package substrate 100, and may contact the first conductive pad 120. The conductive connection member 150 may be electrically connected to the circuit patterns through the first conductive pad 120.

The conductive connection member 150 may have a shape of, e.g., a bump or a ball. In some example embodiments, a plurality of conductive connection members 150 may be spaced apart from each other in the horizontal direction. The conductive connection member 150 may include, e.g., solder that is an alloy of tin, silver, copper, lead, etc.

The first semiconductor chip 200 may include first and second surfaces 202 and 204 opposite to each other in the vertical direction, and the second semiconductor chip 300 may include first and second surfaces 302 and 304 opposite to each other in the vertical direction. The first surface 202 of the first semiconductor chip 200 and the second surface 304 of the second semiconductor chip 300 may face upwardly in the vertical direction, and the second surface 204 of the first semiconductor chip 200 and the first surface 302 of the second semiconductor chip 300 may face downwardly in the vertical direction.

The first and second semiconductor chips 200 and 300 may have active layers adjacent to the respective first surfaces 202 and 302 thereof, and a circuit device, for example, a DRAM device, a flash memory device, etc., may be disposed on each of the active layers. Thus, each of the first and second semiconductor chips 200 and 300 may also be referred to as a memory chip or a memory die. Alternatively, a circuit device, for example, a logic device may be disposed on each of the active layers. Thus, each of the first and second semiconductor chips 200 and 300 may also be referred to as a logic chip or a logic die. The circuit device may include a plurality of circuit patterns.

In some example embodiments, the first and second semiconductor chips 200 and 300 may be chips configured to perform the same function. Alternatively, the first and second semiconductor chips 200 and 300 may be chips configured to perform different functions from each other. The first and second semiconductor chips may collectively form a semiconductor chip stack structure.

A fourth conductive pad 210 may be disposed at a portion of the first semiconductor chip 200 adjacent to the first surface 202 thereof, and may contact a part of the circuit patterns of the first semiconductor chip 200 to be electrically connected thereto. For example, the fourth conductive pad 210 may be on the first surface 202 of the first semiconductor chip 200. A plurality of fourth conductive pads 210 may be spaced apart from each other in the horizontal direction (e.g. a direction into the page as depicted in FIG. 1).

A fifth conductive pad 310 may be disposed at a portion of the second semiconductor chip 300 adjacent to the first surface 302 thereof, and may contact a part of the circuit patterns of the second semiconductor chip 300 to be electrically connected thereto. For example, the fifth conductive pad 310 may be on the first surface 302 of the second semiconductor chip 300. A plurality of fifth conductive pads 310 may be spaced apart from each other in the horizontal direction (e.g. a direction into the page as depicted in FIG. 1).

The fourth and fifth conductive pads 210 and 310 may be disposed in the first and second semiconductor chips 200 and 300, respectively, and thus may also be referred to as first and second chip pads 210 and 310, respectively.

Each of the fourth and fifth conductive pads 210 and 310 may include a metal, e.g., nickel, copper, aluminum, gold, etc.

In some example embodiments, upper surfaces of the second and third conductive pads 132 and 134 on the first surface 102 of the package substrate 100 may be lower than an upper surface of the first semiconductor chip 200 (e.g. the first surface 202).

In some example embodiments, the first adhesion layer 400 may be attached to the second surface 204 of the first semiconductor chip 200, and the first semiconductor chip 200 may be bonded to the first surface 102 of the package substrate 100.

In some example embodiments, the second adhesion layer 700 may be attached to a portion of the first surface 202 of the first semiconductor chip 200 where the fourth conductive pad 210 is not formed, and the first surface 202 of the first semiconductor chip 200 and the first surface 302 of the second semiconductor chip 300 may be bonded with each other through the second adhesion layer 700. For example, the second adhesion layer 700 may be horizontally spaced apart from the conductive pad 210 on the first surface 202 of the first semiconductor chip 200. Thus, the second adhesion layer 700 may not cover upper and lower surfaces of the fourth and fifth conductive pads 210 and 310, respectively.

Each of the first and second adhesion layers 400 and 700 may include, e.g., die attach film (DAF), non-conductive film (NCF), epoxy, etc.

In some example embodiments, a plurality of first bonding wires 610 and a plurality of second bonding wires 620 may be spaced apart from each other in the horizontal direction correspondingly to the fourth and fifth conductive pads 210 and 310, respectively.

In some example embodiments, the first bonding wire 610 may include a first vertical extension portion 614 and a first bonding portion 612. The first vertical extension portion 614 may extend in the vertical direction and contact upper surfaces of the second conductive pad 132 and the first bonding portion 612. The first bonding portion 612 may contact an upper end of the first vertical extension portion 614 and an upper surface of the fourth conductive pad 210 and have a shape of, e.g., a hemisphere.

In some example embodiments, the first vertical extension portion 614 may include a first portion extending in the vertical direction upwardly from the second conductive pad 132, and a second portion extending in the vertical direction downwardly from the first portion thereof. That is, the first vertical extension portion 614 of the first bonding wire 610 may be bent at an interface between the first and second portions thereof.

In some example embodiments, the second bonding wire 620 may include a second vertical extension portion 624 and third and fourth bonding portions 622 and 626. The second vertical extension portion 624 may extend in the vertical direction and contact upper and lower surfaces of the third and fourth bonding portions 622 and 626. The third bonding portion 622 may contact an upper end of the second vertical extension portion 624 and a lower surface of the fifth conductive pad 310 and have a shape of, e.g., a hemisphere. The fourth bonding portion 626 may contact a lower end of the second vertical extension portion 624 and an upper surface of the third conductive pad 134 and have a shape of, e.g., a hemisphere.

In example embodiments, the second vertical extension portion 624 may extend in the vertical direction between the third and fourth bonding portions 622 and 626, however, may not have a shape of a straight line but may be curvy or bent. For example, the third and fourth bonding portions 622 and 626 may be off set from each other in a horizontal direction. For example, the third and fourth bonding portions 622 and 626 may not be vertically aligned. In some example embodiments, the third bonding portion 622 may be an uppermost portion of the second bonding wire 620. In some example embodiments, the third bonding portion 622 may be lower than or coplanar with the first surface 302 of the second semiconductor chip 300.

In some example embodiments, the second adhesion layer 700 may not cover the first and second bonding wires 610 and 620.

In some example embodiments, the first bonding wire 610 may further include a second bonding portion that may contact a lower end of the first vertical extension portion 614 and an upper surface of the second conductive pad 132 and have a shape of, e.g., a hemisphere.

Each of the first and second bonding wires 610 and 620 may include a metal, e.g., copper, aluminum, tungsten, nickel, molybdenum, gold, silver, chromium, tin, titanium, etc.

The molding member 800 may be disposed on the package substrate 100, and may cover the second and third conductive pads 132 and 134, the first semiconductor chip 200, the first and second bonding wires 610 and 620 and the first and second adhesion layers 400 and 700. The molding member 800 may surround a sidewall of the second semiconductor chip 300. The molding member 800 may surround a sidewall of the first semiconductor chip 200. In some example embodiments, an upper surface of the molding member 800 may be coplanar or substantially coplanar with an upper surface of the second semiconductor chip 300.

The molding member 800 may include, e.g., epoxy molding compound (EMC).

The semiconductor package may include the first and second semiconductor chips 200 and 300 sequentially stacked in the vertical direction, and the active layer of the first semiconductor chip 200 that is dispose at a relatively low level may face upwardly, while the active layer of the second semiconductor chip 300 that is dispose at a relatively high level may face downwardly.

Thus, the fourth conductive pad 210 on the active layer of the first semiconductor chip 200, that is, at a portion of the first semiconductor chip 200 adjacent to the first surface 202 of the first semiconductor chip 200 may be electrically connected to the second conductive pad 132 on the first surface 102 of the package substrate 100 through the first bonding wire 610, while the fifth conductive pad 310 beneath the active layer of the second semiconductor chip 300, that is, at a portion of the second semiconductor chip 300 adjacent to the first surface 302 of the second semiconductor chip 300 may be electrically connected to the third conductive pad 134 on the first surface 102 of the package substrate 100 through the second bonding wire 620. The second bonding wire 620 may be disposed between the second semiconductor chip 300 and the package substrate 100.

Accordingly, a conductive pad and a bonding wire connected thereto may not be formed on the second surface 304, that is, the upper surface of the second semiconductor chip 300, and thus the upper surface of the molding member 800 may not be higher than the upper surface of the second semiconductor chip 300 in order to cover the bonding wire. As a result, a vertical thickness of the semiconductor package may be reduced, for example e.g., by about 150 um.

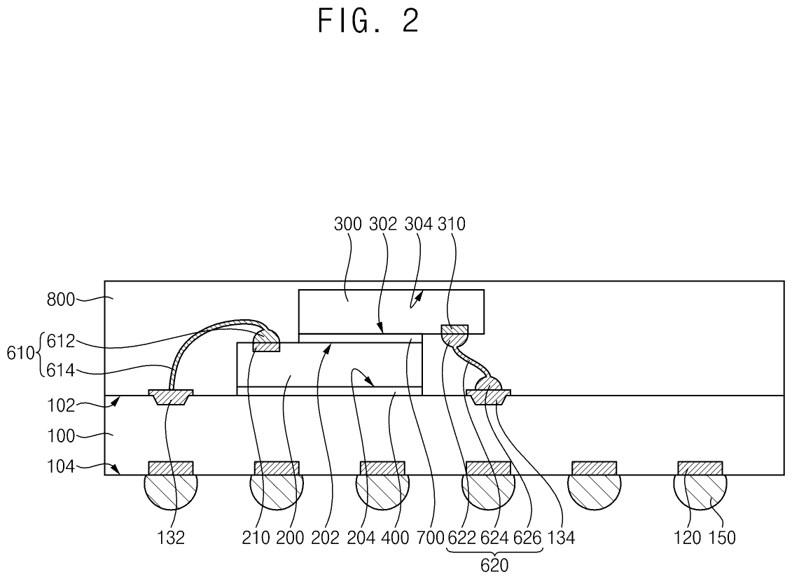

FIG. 2 is a cross-sectional view illustrating a semiconductor package in accordance with some example embodiments.

This semiconductor package may be substantially the same as or similar to that of FIG. 1, except for the height of the molding member, and thus repeated explanations are omitted herein.

Referring to FIG. 2, the molding member 800 may cover an upper surface of the second semiconductor chip 300 as well as the sidewall thereof, and thus the upper surface of the molding member 800 may be higher than the upper surface of the second semiconductor chip 300, for example e.g., by about 20 um.

No bonding wire is disposed on the upper surface of the second semiconductor chip 300, and thus the molding member 800 may not have a thick thickness in order to cover the bonding wire, however, the molding member 800 may have an additional thickness so that the upper surface of the second semiconductor chip 300 is covered by the molding member 800, for example the second semiconductor chip 300 may not be seen through the molding member 800.

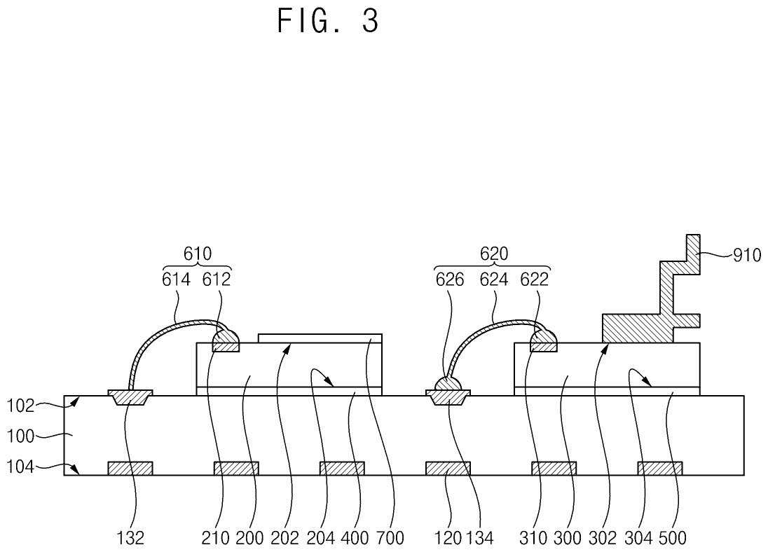

FIGS. 3 to 6 are cross-sectional views illustrating methods of manufacturing a semiconductor package in accordance with example embodiments.

Referring to FIG. 3, first and second semiconductor chips 200 and 300 may be bonded with a first surface 102 of the package substrate 100.

The package substrate 100 may include first and second surfaces 102 and 104 opposite to each other in the vertical direction, and may be, e.g., PCB, which is a multi-layered circuit board including various circuits. The package substrate 100 may include a first conductive pad 120 that is a part of the circuit patterns, and second and third conductive pads 132 and 134 contacting the circuit patterns to be electrically connected thereto.

The first semiconductor chip 200 may include first and second surfaces 202 and 204 opposite to each other in the vertical direction, and the second semiconductor chip 300 may include first and second surfaces 302 and 304 opposite to each other in the vertical direction.

In some example embodiments, a first adhesion layer 400 may be attached to the second surface 204 of the first semiconductor chip 200, a temporary adhesion layer 500 may be attached to the second surface 304 of the second semiconductor chip 300, and each of the first and second semiconductor chips 200 and 300 may be bonded to the first surface of the package substrate 100 through the first adhesion layer 400 and the temporary adhesion layer 500.

The temporary adhesion layer 500 may include a material that may lose adhesion by irradiation of light, e.g., UV or heat. In some example embodiments, the temporary adhesion layer 500 may include release tape.

The first and second semiconductor chips 200 and 300 may include active layers adjacent to the first surfaces 202 and 302, respectively, and a circuit device such as a DRAM device, a flash memory device, etc., may be formed on the active layer. The circuit device may include a plurality of circuit patterns.

Fourth and fifth conductive pads 210 and 310 may be formed at portions of the first and second semiconductor chips 200 and 300, respectively, adjacent to the first surfaces 202 and 302, and may contact the circuit patterns of the first and second semiconductor chips 200 and 300, respectively, to be electrically thereto.

A second adhesion layer 700 may be attached to a portion of the first surface 202 of the first semiconductor chip 200 by, e.g., a spray. In some example embodiments, the second adhesion layer 700 may be formed on a portion the first surface 202 of the first semiconductor chip 200 where the fourth conductive pad 210 is not formed.

A first bonding wire 610 contacting and electrically connecting the second and fourth conductive pads 132 and 210 with each other, and a second bonding wire 620 contacting and electrically connecting the third and fifth conductive pads 134 and 310 with each other may be formed by a wire bonding process using, e.g., a capillary.

In some example embodiments, the first bonding wire 610 may include a first vertical extension portion 614 and a first bonding portion 612. The first vertical extension portion 614 may extend in the vertical direction and contacting upper surfaces of the second conductive pad 132 and the first bonding portion 612. The first bonding portion 612 may contact an upper end of the first vertical extension portion 614 and an upper surface of the fourth conductive pad 210 and have a shape of, e.g., a hemisphere.

In some example embodiments, the second bonding wire 620 may include a second vertical extension portion 624 and third and fourth bonding portions 622 and 626. The second vertical extension 624 may extend in the vertical direction and contact upper surfaces of the third and fourth bonding portions 622 and 626. The third bonding portion 622 may contact an upper end of the second vertical extension portion 624 and an upper surface of the fifth conductive pad 310 and have a shape of, e.g., a hemisphere. The fourth bonding portion 626 may contact a lower end of the second vertical extension portion 624 and an upper surface of the third conductive pad 134 and have a shape of, e.g., a hemisphere.

In some example embodiments, the first bonding wire 610 may further include a second bonding portion that may contact a lower end of the first vertical extension portion 614 and an upper surface of the second conductive pad 132 and have a shape of, e.g., a hemisphere.

A first head picker 910 may be attached to the first surface 302 of the second semiconductor chip 300.

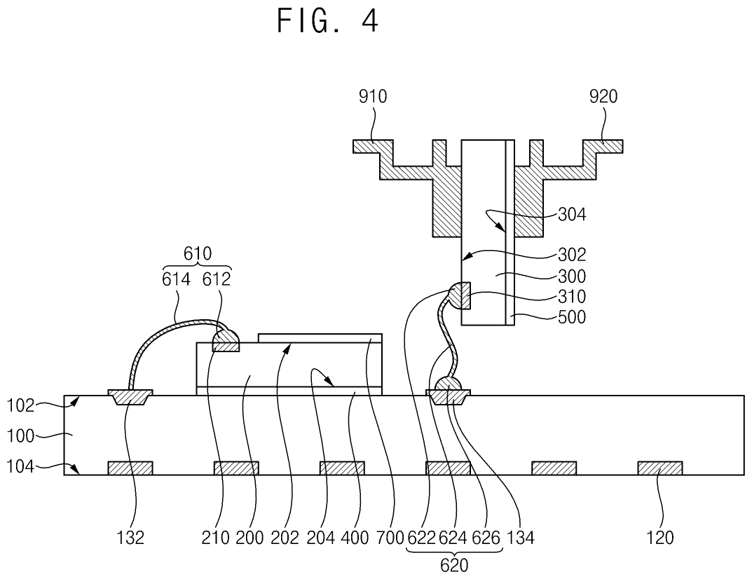

Referring to FIG. 4, the second semiconductor chip 300 may be adsorbed by the first head picker 910, lifted up in the vertical direction, and a second head picker 920 may be attacked to a surface of a temporary adhesion layer 500 on the second surface 304 of the second semiconductor chip 300.

The second bonding wire 620 may be fixed to the fifth and third conductive pads 310 and 134 by the third and fourth bonding portions 622 and 626, respectively, and thus may not be separated from the fifth and third conductive pads 310 and 134.

In some example embodiments, when the second semiconductor chip 300 is lifted up using the first head picker 910, the temporary adhesion layer 500 attached to the second semiconductor chip 300 may be separated from the second semiconductor chip 300 to remain on the first surface 102 of the package substrate 100, and in this case, the temporary adhesion layer 500 may be separated from the package substrate 100 by an additional process.

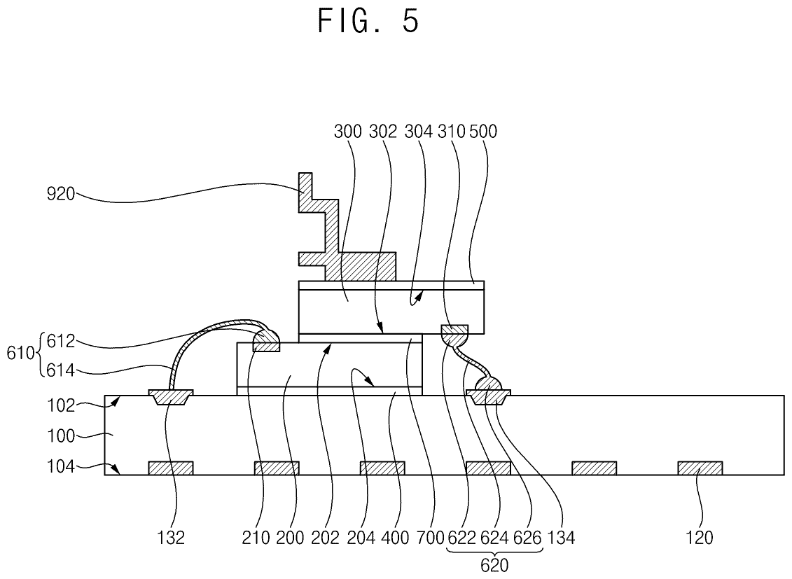

Referring to FIG. 5, the first head picker 910 may be separated from the second semiconductor chip 300, and the second semiconductor chip 300 may be bonded with the second adhesion layer 700 attached to the first surface 202 of the first semiconductor chip 200 so as to be stacked on the first semiconductor chip 200.

Accordingly, the first surface 302 of the second semiconductor chip 300 may face downwardly in the vertical direction, and the second bonding wire 620 may extend in the vertical direction but a portion of the second bonding wire 620 may be bent. The second bonding wire 620 may electrically connect the third and fifth conductive pads 134 and 310 with each other.

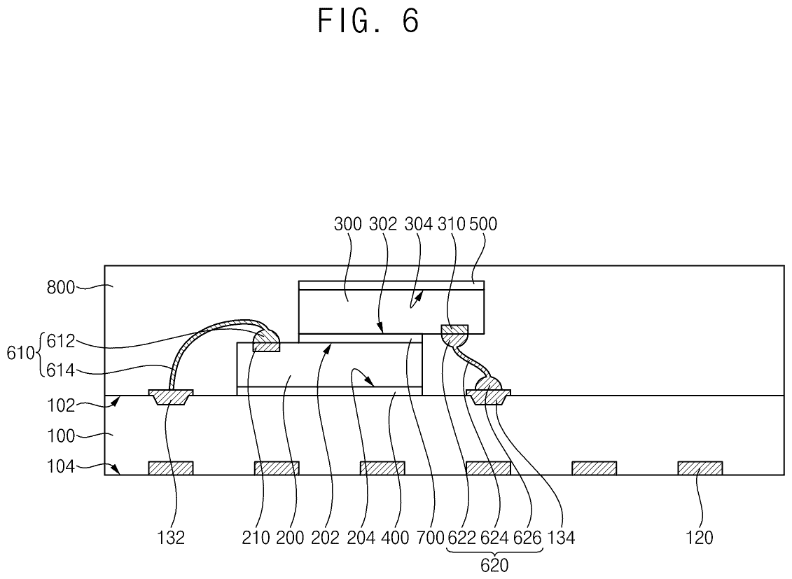

Referring to FIG. 6, the second head picker 920 may be separated from the second semiconductor chip 300 and a molding member 800 may be formed on the package substrate 100 to cover the second and third conductive pads 132 and 134, the first and second semiconductor chips 200 and 300, the first and second bonding wires 610 and 620, the first and second adhesion layers 400 and 700, and the temporary adhesion layer 500.

Referring to FIG. 1 again, a planarization process may be performed on the molding member 800 until the second surface 304 of the second semiconductor chip 300 is exposed, and during the planarization process, the temporary adhesion layer 500 attached to the second semiconductor chip 300 may be removed.

In some example embodiments, the planarization process may include a chemical mechanical polishing (CMP) process.

A conductive connection member 150 may be formed beneath the second surface 104 of the package substrate 100 so that the manufacturing the semiconductor package may be completed.

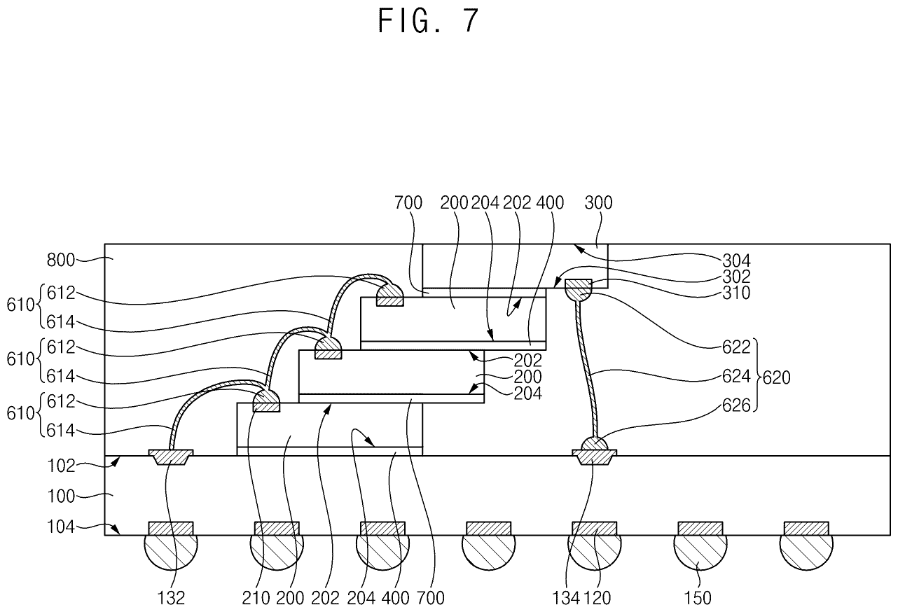

FIG. 7 is a cross-sectional view illustrating a semiconductor package in accordance with some example embodiments.

This semiconductor package may be substantially the same as or similar to that of FIG. 1, except for including a plurality of first semiconductor chips, and thus repeated explanations are omitted herein.

Referring to FIG. 7, the semiconductor package may include a plurality of first semiconductor chips 200 stacked in the vertical direction on the package substrate 100, and the second semiconductor chip 300 on an uppermost one of the first semiconductor chips 200.

That is, the semiconductor chip stack structure may include a lower semiconductor chip stack structure and the second semiconductor chip 300 thereon, and the lower semiconductor chip stack structure may include the plurality of first semiconductor chips 200. FIG. 7 shows that the lower semiconductor chip stack structure includes three first semiconductor chips 200, however, the inventive concept may not be limited thereto, and the lower semiconductor chip stack structure may include more than three first semiconductor chips 200.

In an example embodiment, the first semiconductor chips 200 may be stacked in a cascade pattern. Alternatively, the first semiconductor chips 200 may be stacked in a zigzag pattern. Alternatively, the first semiconductor chips 200 may be stacked in complex pattern including the cascade pattern and the zigzag pattern.

Each of the first semiconductor chips 200 may be electrically connected to one of the first semiconductor chips 200 directly thereunder or the package substrate 100 through the first bonding wire 610. The first bonding wire 610 may include the first vertical extension portion 614 and the first bonding portion 612. The first vertical extension portion 614 may extend in the vertical direction and contact upper surfaces of the first bonding portions 612. The first bonding portion 612 may contact an upper end of the first vertical extension portion 614 and an upper surface of the fourth conductive pad 210 of each of the first semiconductor chips 200 and have a shape of, e.g., a hemisphere.

A second adhesion layer 700 of a plurality of second adhesion layers 700 may be attached to a portion of the first surface 202 of an uppermost one of the first semiconductor chips 200 in the lower semiconductor chip stack structure and the second semiconductor chip 300. Additionally, the uppermost one of the first semiconductor chips 200 may be bonded with each other through the second adhesion layers 700.

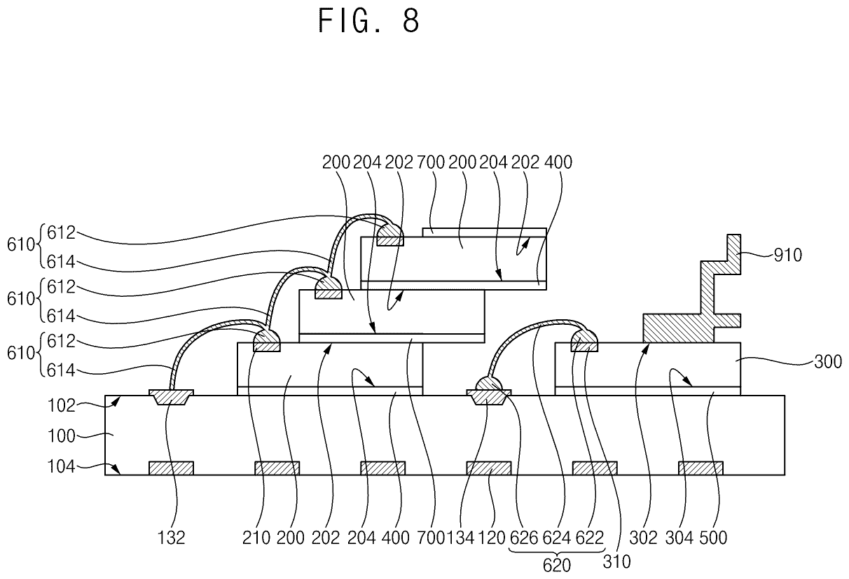

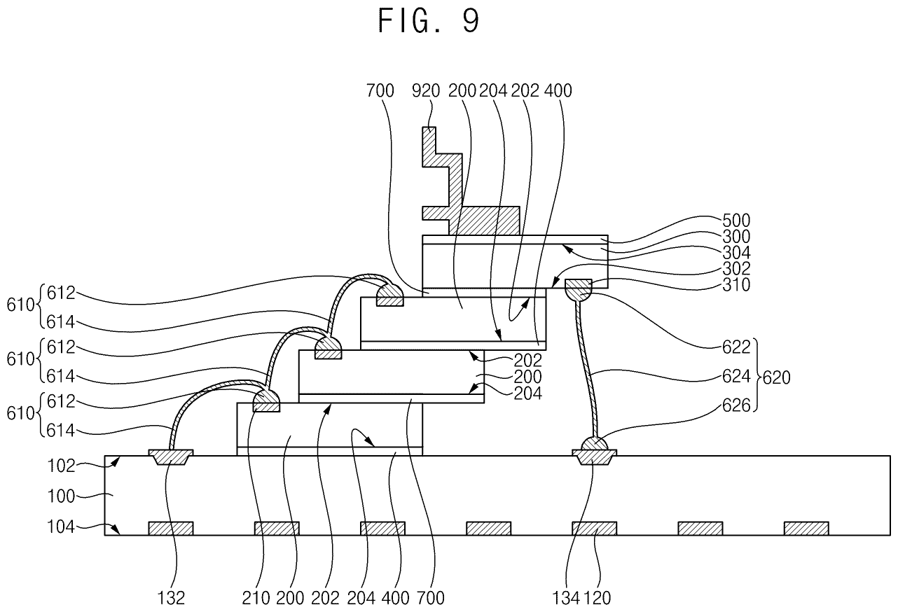

FIGS. 8 and 9 are cross-sectional views illustrating a method of manufacturing a semiconductor package in accordance with example embodiments.

This method may include processes substantially the same as or similar to those illustrated with respect to FIGS. 3 to 6 and FIG. 1, and thus repeated explanations thereof are omitted herein.

Referring to FIG. 8, processes substantially the same as or similar to those illustrated with respect to FIG. 3 may be performed, however, a plurality of first semiconductor chips 200, instead of a single first semiconductor chip 200, may be stacked on the package substrate 100.

The first adhesion layer 400 may be attached to the second surface 204 of one of the first semiconductor chips 200 that is disposed at a relatively high level, and may bonded with one of the first semiconductor chips 200 that is disposed at a relatively low level.

The second adhesion layer 700 may be attached to a portion of the first surface 202 of an uppermost the first semiconductor chips 200.

Additionally, the first bonding wire 610 for electrically connecting the fourth conductive pads 210 of the first semiconductor chips 200 and the second conductive pad 132 on the first surface 102 of the package substrate 100 may be formed by a wire bonding process.

Referring to FIG. 9, processes substantially the same as or similar to those illustrated with respect to FIGS. 4 and 5 may be performed so that the second semiconductor chip 300 may be stacked on the uppermost one of the first semiconductor chips 200.

Referring to FIG. 7 again, processes substantially the same as or similar to those illustrated with respect to FIG. 6 and FIG. 1 may be performed to complete the manufacturing the semiconductor package.

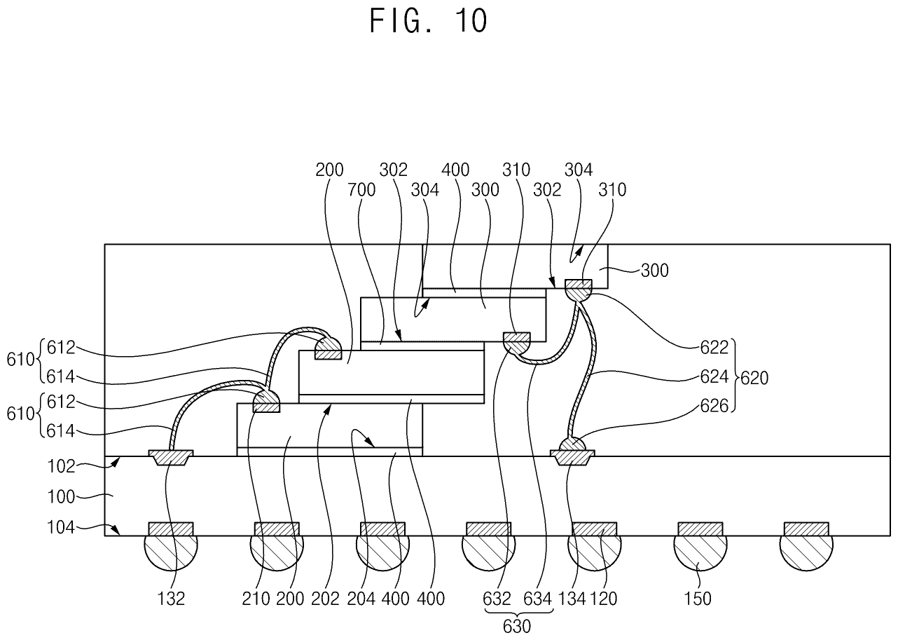

FIG. 10 is a cross-sectional view illustrating a semiconductor package in accordance with some example embodiments.

This semiconductor package may be substantially the same as or similar to that of FIG. 7, except for including a plurality of second semiconductor chips, and thus repeated explanations are omitted herein.

Referring to FIG. 10, the semiconductor package may include a plurality of first semiconductor chips 200 stacked on the package substrate 100 and a plurality of second semiconductor chips 300 stacked on the uppermost one of the first semiconductor chips 200.

That is, the semiconductor chip stack structure of the semiconductor package may include the lower semiconductor chip stack structure and an upper semiconductor chip stack structure thereon, and the lower semiconductor chip stack structure may include the plurality of first semiconductor chips 200 and the upper semiconductor chip stack structure may include the plurality of second semiconductor chips 300.

FIG. 10 shows that the lower semiconductor chip stack structure includes two first semiconductor chips 200 and the upper semiconductor chip stack structure includes two second semiconductor chips 300, however, the inventive concept may not be limited thereto, and the lower and upper semiconductor chip stack structures may include more than two first and second semiconductor chips 200 and 300, respectively.

The first surface 302 of each of the second semiconductor chips 300 may face downwardly in the vertical direction, and the fifth conductive pad 310 may be disposed at a portion of each of the second semiconductor chips 300 adjacent to the first surface 302. The second bonding wire 620 may be disposed between the fifth conductive pad 310 of the uppermost one of the second semiconductor chips 300 and the third conductive pad 134 on the first surface 102 of the package substrate 100, and may electrically connect the fifth conductive pad 310 and the third conductive pad 134 to each other.

A third bonding wire 630 may be disposed between and electrically connect the fifth conductive pad 310 of one of the second semiconductor chips 300 disposed at a relatively high level and the fifth conductive pad 310 of one of the second semiconductor chips 300 disposed at a relatively low level. In some example embodiments, the third bonding wire 630 may include a third vertical extension portion 634 and a fifth bonding portion 632. The third vertical extension portion 634 may extend in the vertical direction and contact a lower surface of the fifth bonding portion 632 and a lower surface of the third bonding portion 622 of the second bonding wire 620. The fifth bonding portion 632 may contact a lower end of the third vertical extension portion 634 and the lower surface of the fifth conductive pad 310 and have a shape of, e.g., a hemisphere.

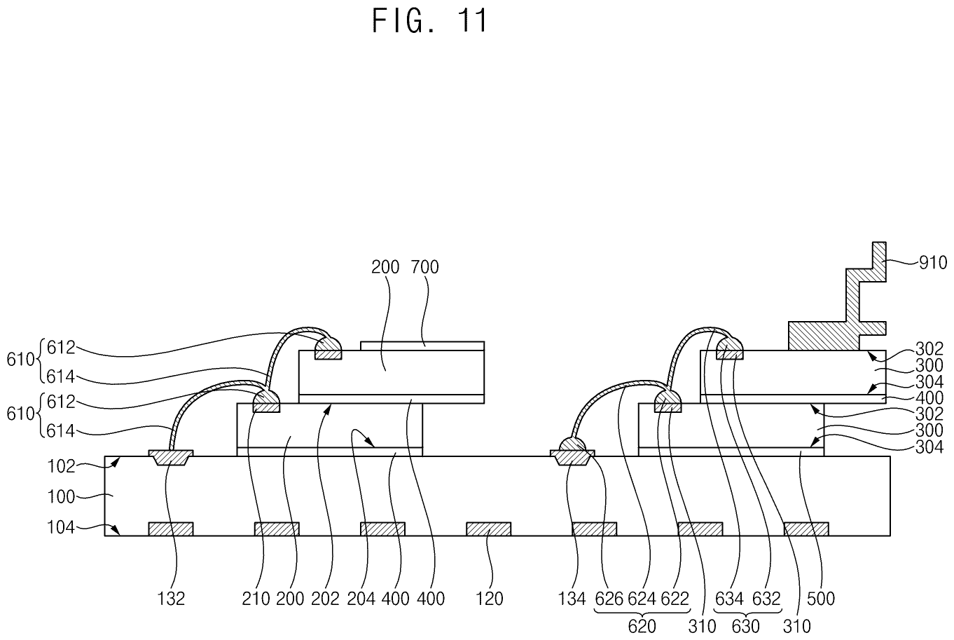

FIG. 11 is a cross-sectional view illustrating a method of manufacturing a semiconductor package in accordance with example embodiments.

This method may include processes substantially the same as or similar to those illustrated with respect to FIGS. 8 and 9 and FIG. 7, and thus repeated explanations thereof are omitted herein.

Referring to FIG. 11, processes substantially the same as or similar to those illustrated with respect to FIG. 8 may be performed, however, a plurality of second semiconductor chips 300 may stacked on the first surface 102 of the package substrate 100.

The first adhesion layer 400 may be attached to the second surface 304 of a first one of the second semiconductor chips 300 stacked at a relatively high level, and the first one of the semiconductor chips 300 may be bonded with a second one of the second semiconductor chips 300 stacked at a relatively low level.

Additionally, a third bonding wire 630 may be formed to electrically connect the fifth conductive pads 310 of the first and second ones of the second semiconductor chips 300 with each other by a wire bonding process. In some example embodiments, the third bonding wire 630 may include a third vertical extension portion 634 and a fifth bonding portion.

The first head picker 910 may be attached to the first surface 302 of an uppermost one of the second semiconductor chips 300.

Referring to FIG. 10, processes substantially the same as or similar to those illustrated with respect to FIG. 9 and FIG. 7 may be performed so that the second semiconductor chips 300 may be stacked on an uppermost one of the first semiconductor chips 200, the molding member 800 may be formed on the package substrate 100, a planarization process may be performed on the molding member 800, and the conductive connection member 150 may be formed to complete the manufacturing the semiconductor package.

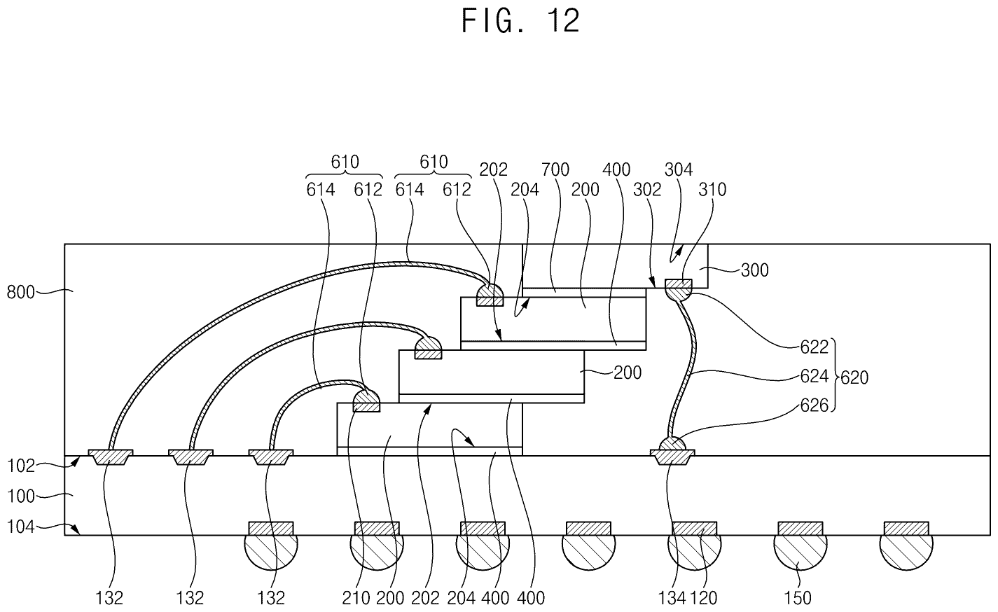

FIG. 12 is a cross-sectional view illustrating a semiconductor package in accordance with example embodiments.

This semiconductor package may be substantially the same as or similar to that of FIG. 7, except for the connection between each of the first semiconductor chips and the package substrate, and thus repeated explanations are omitted herein.

Referring to FIG. 12, the first semiconductor chips 200 included in the lower semiconductor chip stack structure may be electrically connected to the second conductive pads 132 on the first surface 102 of the package substrate 100 through corresponding ones of the first bonding wires 610.

In the semiconductor package of FIG. 7, each of the first semiconductor chips 200 except for a lowermost one of the first semiconductor chips 200 may be electrically connected to the package substrate 100 through the first bonding wires 610 that may connect the fourth conductive pads 210 of ones of the first semiconductor chips 200 under each of the first semiconductor chips 200, while in the semiconductor package of FIG. 12, each of the first semiconductor chips 200 may be electrically connected to the package substrate 100 through the first bonding wire 610 that may directly connect the fourth conductive pad 210 of each of the first semiconductor chips 200 and the package substrate 100.

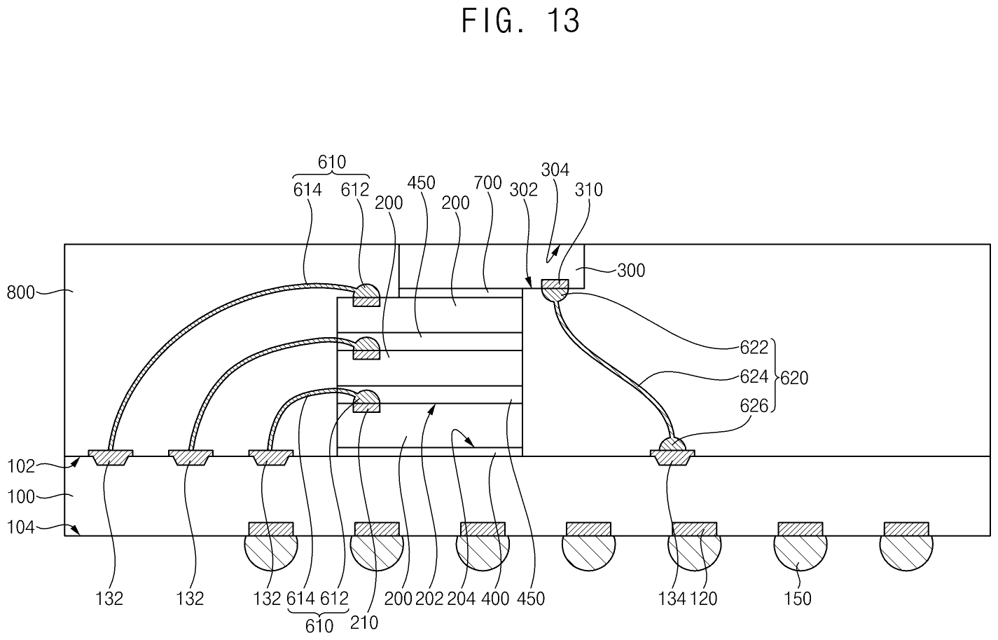

FIG. 13 is a cross-sectional view illustrating a semiconductor package in accordance with some example embodiments.

This semiconductor package may be substantially the same as or similar to that of FIG. 7, except for the lower semiconductor chip stack structure, and thus repeated explanations are omitted herein.

Referring to FIG. 13, the first semiconductor chips 200 included in the lower semiconductor chip stack structure may not be stacked in a cascade pattern or a zigzag pattern, but edges of the first semiconductor chips 200 may be aligned (e.g. coplanar) with each other in the vertical direction.

A portion of the first bonding wire 610 contacting an upper surface of the fourth conductive pad 210 of each of the first semiconductor chips 200 except for the uppermost one of the first semiconductor chips 200 may be covered by a third adhesion layer 450 attached to the second surface 204 of one of the first semiconductor chips 200 disposed at a level higher than that of each of the first semiconductor chips 200. Thus, a thickness in the vertical direction of the third adhesion layer 450 may be greater than a thickness in the vertical direction of the first adhesion layer 400.

The foregoing is illustrative of some example embodiments and is not to be construed as limiting thereof. Although a few example embodiments have been described, those skilled in the art will readily appreciate that many modifications are possible in example embodiments without materially departing from the novel teachings and advantages of the present inventive concepts. Accordingly, all such modifications are intended to be included within the scope of example embodiments as defined in the claims.

What is claimed is:

1. A semiconductor package comprising:
a package substrate having first and second substrate pads;
a first semiconductor chip on the package substrate, the first semiconductor chip including a first chip pad;
a second semiconductor chip on the first semiconductor chip, the second semiconductor chip including a second chip pad on a lower surface of the second semiconductor chip;
a first bonding wire contacting the first substrate pad and the first chip pad; and
a second bonding wire contacting the second substrate pad and the second chip pad,
wherein an uppermost portion of the second bonding wire is lower than or coplanar with the lower surface of the second semiconductor chip.

2. The semiconductor package according to claim 1, wherein the second bonding wire includes:
a first bonding portion contacting a lower surface of the second chip pad;
a second bonding portion contacting an upper surface of the second substrate pad; and
a vertical extension portion contacting the first and second bonding portions and extending in a vertical direction between the first and second bonding portions.

3. The semiconductor package according to claim 2, wherein each of the first and second bonding portions has a shape of a hemisphere, and the vertical extension portion is curved.

4. The semiconductor package according to claim 1, further comprising:
an adhesion layer contacting a portion of an upper surface of the first semiconductor chip and a portion of the lower surface of the second semiconductor chip.

5. The semiconductor package according to claim 4, wherein the adhesion layer does not cover the first and second chip pads and the first and second bonding wires.

6. The semiconductor package according to claim 1, further comprising:
a molding member on the package substrate, the molding member covering the first semiconductor chip, covering the first and second bonding wires, and surrounding a sidewall of the second semiconductor chip.

7. The semiconductor package according to claim 6, wherein an upper surface of the molding member is coplanar with an upper surface of the second semiconductor chip.

8. The semiconductor package according to claim 6, wherein the molding member covers an upper surface of the second semiconductor chip.

9. The semiconductor package according to claim 1, wherein an upper surface of each of the first and second substrate pads is lower than an upper surface of the first semiconductor chip.

10. A semiconductor package comprising:
a package substrate having first and second substrate pads;
a lower semiconductor chip stack structure including first semiconductor chips stacked on the package substrate in a vertical direction perpendicular to an upper surface of the package substrate, each of the first semiconductor chips including a first chip pad;
a second semiconductor chip on the lower semiconductor chip stack structure, the second semiconductor chip including a second chip pad on a bottom surface of the second semiconductor chip;
a first bonding wire contacting the first chip pad of a lowermost one of the first semiconductor chips and the first substrate pad; and
a second bonding wire contacting the second substrate pad and the second chip pad,
wherein an upper surface of each of the first and second substrate pads is lower than an upper surface of the lowermost one of the first semiconductor chips.

11. The semiconductor package according to claim 10, further comprising:
a third bonding wire contacting the first chip pads of neighboring first semiconductor chips in the vertical direction.

12. The semiconductor package according to claim 11, wherein the first semiconductor chips are stacked in the vertical direction in a cascade pattern or a zigzag pattern.

13. The semiconductor package according to claim 10, further comprising:
third substrate pads spaced apart from each other in a horizontal direction substantially parallel to the upper surface of the package substrate; and
third bonding wires contacting the first chip pad of each of the first semiconductor chips, respectively, except for the lowermost one of the first semiconductor chips, and each third bonding wire corresponding to a third substrate pad of the third substrate pads.

14. The semiconductor package according to claim 13, wherein the first semiconductor chips are stacked in the vertical direction in a cascade pattern or a zigzag pattern.

15. The semiconductor package according to claim 13, wherein edges of the first semiconductor chips, respectively, are aligned with each other in the vertical direction.

16. The semiconductor package according to claim 10, further comprising:
a third semiconductor chip between the lower semiconductor chip stack structure and the second semiconductor chip; and
a third bonding wire contacting the second and third substrate pads.

17. The semiconductor package according to claim 16, further comprising:
a first adhesion layer contacting a portion of an upper surface of an uppermost one of the first semiconductor chips included in the lower semiconductor chip stack structure and a portion of a lower surface of the third semiconductor chip.

18. The semiconductor package according to claim 16, further comprising:
a second adhesion layer contacting an upper surface of the third semiconductor chip and a portion of a lower surface of the second semiconductor chip.

19. A semiconductor package comprising:
a package substrate having first and second substrate pads;
a lower semiconductor chip stack structure including first semiconductor chips stacked on the package substrate in a vertical direction substantially perpendicular to an upper surface of the package substrate, each of the first semiconductor chips including a first chip pad;
a second semiconductor chip on the lower semiconductor chip stack structure, the second semiconductor chip including a second chip pad on a lower surface of the second semiconductor chip;
a first adhesion layer contacting a portion of an upper surface of an uppermost one of the first semiconductor chips included in the lower semiconductor chip stack structure and a portion of the lower surface of the second semiconductor chip;
a first bonding wire contacting the first chip pad of a lowermost one of the first semiconductor chips and the first substrate pad;
a second bonding wire contacting the first chip pads of neighboring ones of the first semiconductor chips in the vertical direction;
a third bonding wire contacting the second substrate pad and the second chip pad; and
a molding member on the package substrate, the molding member covering the lower semiconductor chip stack structure, the first adhesion layer, and the first to third bonding wires and surrounding a sidewall of the second semiconductor chip,
wherein an upper portion of the third bonding wire is lower than or coplanar with the lower surface of the second semiconductor chip.

20. The semiconductor package according to claim 19, wherein an upper surface of the molding member is coplanar with an upper surface of the second semiconductor chip.
